(19) United States
(12) Patent Application Publication
(10) Pub. No.: US 2015/0212540 A1
(43) Pub. Date: Jul. 30, 2015

(54) LIGHT DIFFUSING TOUCH PANEL AND MANUFACTURING METHOD FOR SAME, AS WELL AS DISPLAY DEVICE

(71) Applicant: Sharp Kabushiki Kaisha, Osaka-shi, Osaka (JP)

(72) Inventors: Masahiro Tsujimoto, Osaka-shi (JP); Tsuyoshi Kamada, Osaka-shi (JP); Shohei Katsuta, Osaka-shi (JP); Daisuke Shinozaki, Osaka-shi (JP)

(21) Appl. No.: 14/420,072

(22) PCT Filed: Aug. 5, 2013
(86) PCT No.: PCT/JP2013/071104

§ 371 Date: Feb. 6, 2015

(30) Foreign Application Priority Data
Aug. 10, 2012 (JP) 2012-178368

(51) Int. Cl. G06F 1/16; G03F 7/16; G03F 7/30; G03F 7/20; G06F 3/044; G06F 3/041

(52) U.S. Cl. CPC G06F 1/16; G06F 3/044; G06F 3/0412; G03F 7/30; G03F 7/20; G03F 7/16; G06F 2203/04103

(57) ABSTRACT

Provided are a light diffusing touch panel of a thin type and a low coat, and a manufacturing method for the same. A light diffusing touch panel 7 includes a base material 39 having light-transmitting properties, a light absorbing layer 40 that is formed on one face side of the base material 39, and a light diffusing portion 41 that is formed on the one face side of the base material 39 in the same manner as the light absorbing layer 40, in which the light diffusing portion 41 has a light emission end face on the base material 39 side, and has a light incidence end face of which an area is greater than the area of the light emission end face on an opposite side to the base material 39 side, a height to the light emission end face from the light incidence end face of the light diffusing portion 41 is greater than a layer thickness of the light absorbing layer 40, and the base material 39 or the light absorbing layer 40 forms any one of a dielectric layer and a pair of conductive films which are arranged so as to overlap the dielectric layer.

### TECHNICAL FIELD

The present invention relates to a light diffusing touch panel and a manufacturing method for the same, as well as a display device.

### BACKGROUND ART

As a display of portable type electronic apparatuses including a mobile phone, or a television, a personal computer, or the like, a liquid crystal display device is widely used. However, it has been generally known that while the liquid crystal display device is excellent in viewability from a front side, a viewing angle is narrow, and various plans have been made in order to widen the viewing angle. As one of such plans, a configuration of including a member (referred to as a light diffusing member, hereinafter) for diffusing light which is emitted from a display body such as a liquid crystal panel, on a viewing side of the display body, is considered.

For example, as a light diffusing member, a light dispersion film configuring a portion of a rear projection screen is known (for example, see PTL 1). The light dispersion film has a light-transmitting substrate and a plurality of light diffusing structures which are arranged on the light-transmitting substrate.

On the other hand, a demand for a touch operable display device becomes increasingly large. However, since a display device having a light diffusing member and a touch panel is configured only by simply stacking the light diffusing member and the touch panel through an adhesion layer, there are problems, in general, of not only increasing a cost, but also lowering display quality when the number of configuration members becomes large and a thickness becomes large.

### CITATION LIST

### Patent Literature

PTL 1: Japanese Unexamined Patent Application Publication (Translation of PCT Application) No. 2007-514202

### SUMMARY OF INVENTION

### Technical Problem

The present invention is made in order to solve the above problems, and an object thereof is to provide a light diffusing touch panel of a thin type and a low cost, and a manufacturing method for the same. Moreover, the object thereof is to provide a display device which includes the light diffusing touch panel, and is excellent in display quality.

### Solution to Problem

A light diffusing touch panel according to the present invention includes a base material having light-transmitting properties, a light absorbing layer that is formed on one face side of the base material, and a light diffusing portion that is formed on the one face side of the base material in the same manner as the light absorbing layer, in which the light diffusing portion has a light emission end face on the base material side and has a light incidence end face of which an area is greater than the area of the light emission end face on an opposite side to the base material side, a height to the light emission end face from the light incidence end face of the light diffusing portion is greater than a layer thickness of the light absorbing layer, and the base material or the light absorbing layer forms any one of a dielectric layer and a pair of conductive films which are arranged so as to overlap the dielectric layer.

In the light diffusing touch panel of the present invention, it is preferable that the base material form the dielectric layer.

In the light diffusing touch panel of the present invention, it is preferable that the light absorbing layer form one of the pair of conductive films, and the other of the pair of conductive films be arranged on the other face side of the base material.

In the light diffusing touch panel of the present invention, it is preferable that one of the pair of conductive films be arranged between the base material and the light absorbing layer, and the other of the pair of conductive films be arranged on the other face side of the base material.

In the light diffusing touch panel of the present invention, it is preferable that the light absorbing layer form one of the pair of conductive films, and the other of the pair of conductive films be arranged on the other face side of the base material through an adhesive.

In the light diffusing touch panel of the present invention, it is preferable that a second light absorbing layer be further arranged on the other face of the base material, the light absorbing layer form one of the pair of conductive films, the second light absorbing layer form the other of the pair of conductive films, and a conductive direction of one of the pair of conductive films be orthogonal to the conductive direction of the other of the pair of conductive films.

In the light diffusing touch panel of the present invention, it is preferable that air be present in a space between the plurality of light diffusing portions.

In the light diffusing touch panel of the present invention, it is preferable that air be present in a space between the plurality of light diffusing portions, the air form the dielectric layer, the light absorbing layer form one of the pair of conductive films, and the other of the pair of conductive films be arranged on the light incidence end face side of the light diffusing portion.

In the light diffusing touch panel of the present invention, it is preferable that among the plurality of light diffusing portions, a dimension of the light emission end face of at least one light diffusing portion be different from the dimensions of the light emission end faces of other light diffusing portions.

In the light diffusing touch panel of the present invention, it is preferable that among the plurality of light diffusing portions, an inclination angle of a side face of at least one light diffusing portion be different from the inclination angles of the side faces of other light diffusing portions.

In the light diffusing touch panel of the present invention, it is preferable that among the plurality of light diffusing portions, an inclination angle of a side face of at least one light diffusing portion vary depending on a place.

In the light diffusing touch panel of the present invention, it is preferable that a planar shape of the light diffusing portion which is seen from a normal direction of one face of the base material be a round shape or a polygonal shape.

A manufacturing method for a light diffusing touch panel according to the present invention includes a step of forming a light absorbing layer that forms one of a pair of conductive films on one face of a base material having light-transmitting properties, a step of forming, on one face of the base material, a negative type photosensitive resin layer having light-transmitting properties so as to cover the light absorbing layer, a step of irradiating the negative type photosensitive resin layer with diffused light through an opening portion of the light absorbing layer from an opposite face to the one face of the base material where the light absorbing layer and the negative type photosensitive resin layer are formed, a step of developing the negative type photosensitive resin layer where the irradiation of the diffused light is finished and forming, on the one face of the base material, a light diffusing portion that has a light emission end face on the base material side and has a light incidence end face of which an area is greater than the area of the light emission end face on an opposite side to the base material side, and a step of forming the other of the pair of conductive films on the other face side of the base material.

A display device according to the present invention includes a display body, and a viewing angle widening member that is arranged on a viewing side of the display body and emits light in a state of having angle distribution of the light which is incident from the display body wider than that before the incidence, in which the viewing angle widening member is configured of the light diffusing touch panel according to the present invention.

In the display device of the present invention, it is preferable that the display body have a plurality of pixels which form a display image, and among the plurality of light diffusing portions of the light diffusing touch panel, an average gap between adjacent light diffusing portions is smaller than a gap between the pixels of the display body.

In the display device of the present invention, it is preferable that the display body have a light source and a light modulation element that modulates light from the light source, and the light source emit the light having directivity.

In the display device of the present invention, it is preferable that the display body is a liquid crystal display element.

### Advantageous Effects of Invention

According to the present invention, it is possible to provide a light diffusing touch panel of a thin type and a low cost.

### BRIEF DESCRIPTION OF DRAWINGS

FIG. 1 is a perspective view illustrating a liquid crystal display device according to a first embodiment of the present invention.

FIG. 2 is a cross-sectional view illustrating the liquid crystal display device according to the first embodiment of the present invention.

FIG. 3 is a cross-sectional view illustrating a liquid crystal panel in the liquid crystal display device according to the first embodiment of the present invention.

FIG. 4 is a diagram illustrating a light diffusing touch panel in the liquid crystal display device according to the first embodiment of the present invention, where (A) is a cross-sectional view and (B) is a plan view which is seen from a viewing side.

FIG. 5 is a schematic diagram illustrating an operation of a touch panel.

FIG. 6 is a perspective view illustrating the light diffusing touch panel according to the first embodiment of the present invention, following a sequence of manufacturing steps.

FIG. 7 is a perspective view illustrating an example of a manufacturing device for the light diffusing touch panel according to the first embodiment of the present invention.

FIG. 8 is a perspective view illustrating a main portion of the manufacturing device for the light diffusing touch panel according to the first embodiment of the present invention.

FIG. 9 is a schematic diagram illustrating the operation of the light diffusing touch panel.

FIG. 10 is a diagram illustrating an effect of a viewing angle widening film according to the first embodiment of the present invention.

FIG. 11 is a diagram illustrating a liquid crystal display device according to a second embodiment of the present invention, where (A) is a longitudinal cross-sectional view and (B) is a plan view which is seen from the viewing side.

FIG. 12 is a diagram illustrating a liquid crystal display device according to a third embodiment of the present invention, where (A) is a longitudinal cross-sectional view and (B) is a plan view which is seen from the viewing side.

FIG. 13 is a longitudinal cross-sectional view illustrating a liquid crystal display device according to a fourth embodiment of the present invention.

FIG. 14 is a longitudinal cross-sectional view illustrating a liquid crystal display device according to a fifth embodiment of the present invention.

FIG. 15 is a diagram illustrating a liquid crystal display device according to a sixth embodiment of the present invention, where (A) is a longitudinal cross-sectional view, (B) is a plan view which is seen from the viewing side, and (C) is a plan view which is seen from the viewing side.

### DESCRIPTION OF EMBODIMENTS

A light diffusing touch panel and a manufacturing method for the same, as well as a display device according to embodiments of the present invention, will be described

Furthermore, the embodiments are specifically described in order to understand better the gist of the invention, and do not limit the present invention unless particularly specified.

### First Embodiment

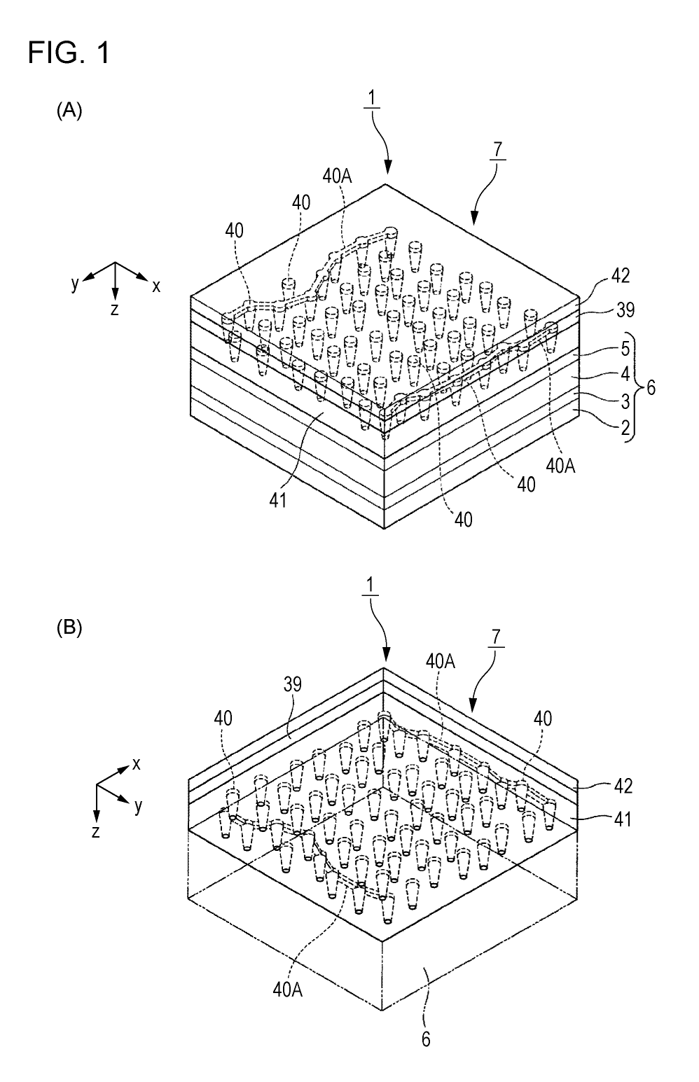

Hereinafter, a first embodiment of the present invention will be described, using FIG. 1 to FIG. 9.

In the first embodiment, an example of a transmission type liquid crystal display device including a liquid crystal panel as a display body, will be described.

Furthermore, in all of the following drawings, in order to easily see each component, the components are seen by varying scales of dimensions according to the components.

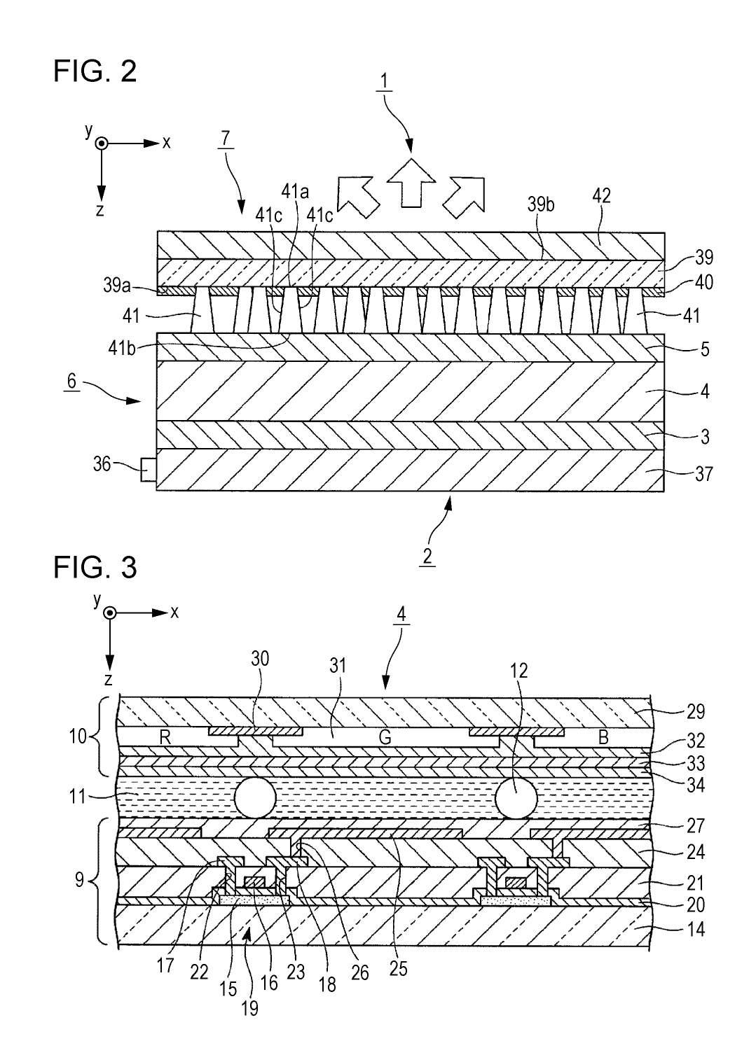

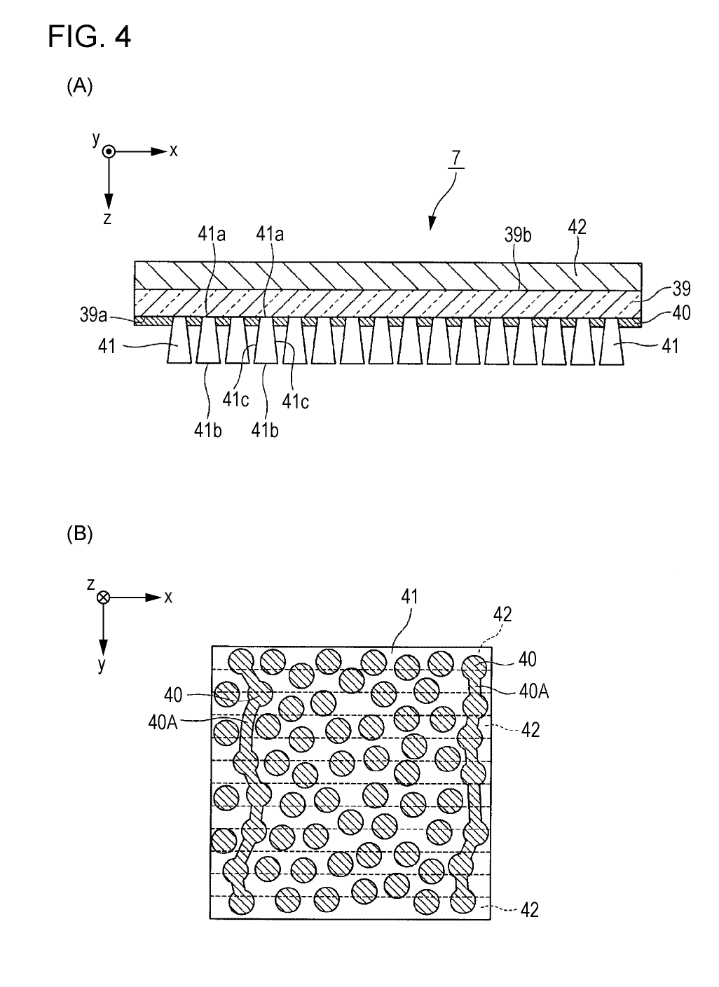

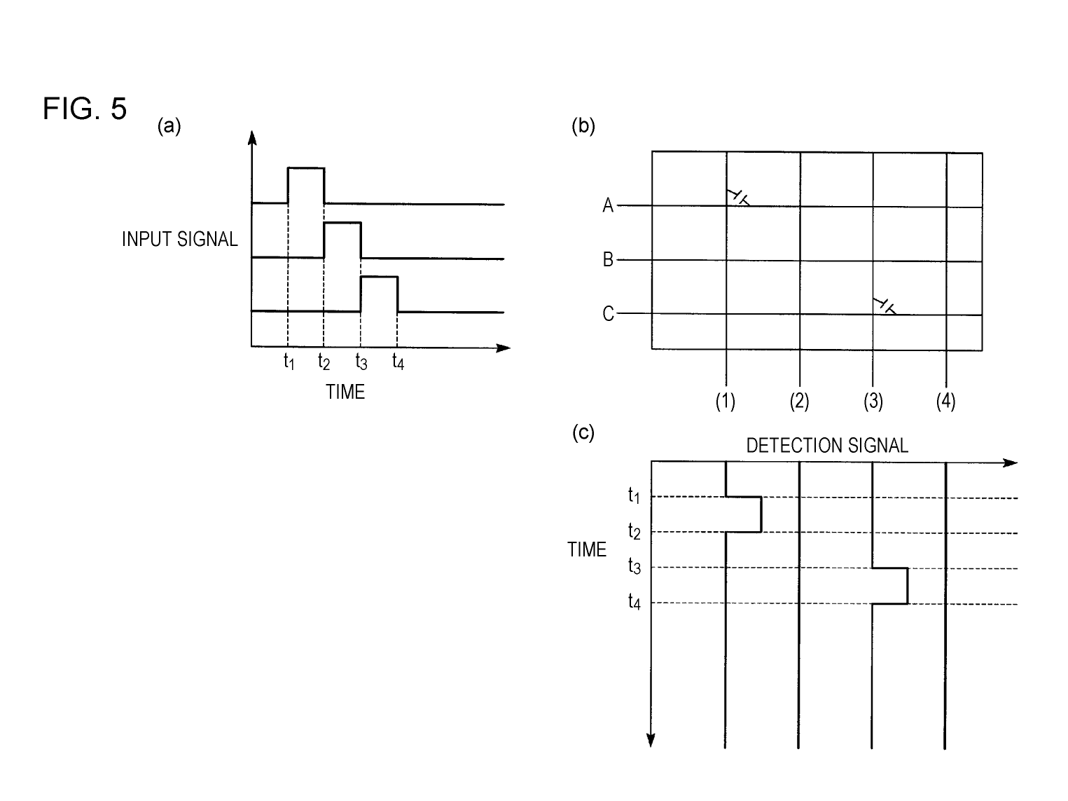

FIG. 1(A) is a perspective view of a liquid crystal display device according to the first embodiment which is seen from obliquely upwards (viewing side), and FIG. 1(B) is a perspective view of the liquid crystal display device according to the first embodiment which is seen from obliquely downwards (rear face side). FIG. 2 is a longitudinal cross-sectional view of the liquid crystal display device according to the first embodiment. FIG. 3 is a longitudinal cross-sectional view of a liquid crystal panel in the liquid crystal display device according to the first embodiment. FIG. 4 is a diagram illustrating a light diffusing touch panel in the liquid crystal display device according to the first embodiment of the present invention, (A) is a cross-sectional view, and (B) is a plan view which is seen from the viewing side. FIG. 5 is schematic diagram illustrating an operation of a touch panel. As shown in FIG. 1(A), FIG. 1(B), and FIG. 2, a liquid crystal display device (display device) 1 according to the first embodiment, is schematically configured of a liquid crystal display body (display body) 6 having a backlight (light source) 2, a first polarizing plate 3, a liquid crystal panel 4 and a second polarizing plate 5, and a light diffusing touch panel (viewing angle widening member, light diffusing member) 7.

In FIG. 1(A) and FIG. 2, one sheet of the plate-shaped liquid crystal panel 4 is schematically shown, but the detailed structure thereof will be described later.

An observer will see a display from an upper side of the liquid crystal display device 1 where the light diffusing touch panel 7 is arranged, in FIG. 2. Accordingly, in the following description, the side where the light diffusing touch panel 7 is arranged, is referred to as a viewing side, and the side where the backlight 2 is arranged, is referred to as a rear face side.

In the liquid crystal display device 1 of the first embodiment, light which is emitted from the backlight 2 is modulated by the liquid crystal panel 4, and a predetermined image or character is displayed according to the modulated light. Moreover, if the light which is emitted from the liquid crystal panel 4 transmits the light diffusing touch panel 7, the light is emitted from the light diffusing touch panel 7 in a state of widening angle distribution of the emitted light than that before the incidence to the light diffusing touch panel 7. Hereby, the observer can visually confirm the display having a wide viewing angle.

Hereinafter, the light diffusing touch panel 7 will be described in detail.

FIG. 4(A) is a longitudinal cross-sectional view of the light diffusing touch panel 7, and FIG. 4(B) is a plan view of the light diffusing touch panel 7 which is seen from the viewing side. Furthermore, FIG. 4(B) shows the state of being cut by an interface between a base material 39 and a black layer 40.

As shown in FIG. 4(B), the black layer 40 becomes an electrode of a y direction, and a conductive film 42 becomes an electrode of an x direction.

As shown in FIG. 4(A), the light diffusing touch panel 7 is schematically configured of the base material 39, a plurality of black layers (light absorbing layer) 40 which are formed on one face (opposite face to the viewing side) 39a of the base material 39, a light diffusing portion 41 which is formed on one face 39a side of the base material 39 in the same manner as the black layer 40, and the conductive film 42 which is formed on the other face (face of the viewing side) 39b of the base material 39.

As shown in FIG. 2, the light diffusing touch panel 7 is arranged on the second polarizing plate 5 of the liquid crystal display body 6, in a posture of directing the side where the light diffusing portion 41 is arranged toward the second polarizing plate 5, and directing the base material 39 side toward the viewing side.

Furthermore, if the conductive film 42 is sufficiently small, the light diffusing touch panel 7 can mostly maintain transparency even when the conductive film 42 is non-transparent. Therefore, a material forming the conductive film 42 may be a transparent material, or may be a non-transparent material. In other embodiments, it is similar thereto.

For example, in the base material 39, a material manufactured by transparent resin such as triacetyl cellulose (TAC) film, polyethylene terephthalate (PET), polycarbonate (PC), polyethylene naphthalate (PEN) and a polyether sulfone (PES) film, is preferably used. In a manufacturing step described later, the base material 39 becomes the groundwork in a case of coating the materials of the black layer 40 and the light diffusing portion 41 later, and is necessary to have heat resistance and mechanical strength in heat treatment of the manufacturing step. Consequently, in the base material 39, a material manufactured by glass may be used, in addition to the base material manufactured by the resin. However, it is preferable that a thickness of the base material 39 is thin at degrees of not damaging the heat resistance and the mechanical strength. The reason thereof is as follows. A blur of the display may occur as the degrees of thickening the thickness of the base material 39. Moreover, it is preferable that total light transmittance of the base material 39 is 90% or more by regulations of JIS K7361-1. If the total light transmittance is 90% or more, the sufficient transparency is obtained. In the first embodiment, a base material manufactured by transparent resin of which the thickness is 100 μm is used as an example.

The black layer 40 has a round shape or an elliptical shape, when seen from the viewing side. As shown in FIG. 4(A), on one face 39a of the base material 39, the black layers 40 are randomly arranged when seen from the viewing side. Furthermore, an x axis is defined by a horizontal direction of a screen of the liquid crystal panel 4, a y axis is defined by a vertical direction of the screen of the liquid crystal panel 4, and a z axis is defined by a thickness direction of the liquid crystal display device 1. Additionally, as shown in FIG. 4(B), the black layers 40 having the round shape or the elliptical shape, are formed in parallel at a predetermined gap along a y axis direction of the base material 39, so as to form a line shape (belt shape) when seen from the viewing side, and are connected to each other by conductive portions 40A which are formed of the same material as the black layer 40. Hereby, the black layer 40 has conductivity, along the y axis direction of the base material 39. Still more, the black layer 40 and the conductive portion 40A may not be formed of the same material.

The black layer 40 is configured of an organic material having light absorbing properties and photosensitive properties such as black resist, as an example. In addition, a metal film such as Cr (chrome) or a multilayer film of Cr and Cr oxide, may be used. A layer thickness of the black layer 40 is configured to be smaller than a height to a light emission end face 41a from a light incidence end face 41b of the light diffusing portion 41. Moreover, in a space between a plurality of light diffusing portions 41, the black layer 40 is present in a portion coming into contact with one face 39a of the base material 39, and air is present in a portion other than the above portion.

The light diffusing portion 41 is formed in region other than a formation region of the black layer 40, among one face 39a of the base material 39.

For example, the light diffusing portion 41 is configured of the organic material having the light-transmitting properties and the photosensitive properties such as acryl resin or epoxy resin. Moreover, it is preferable that the total light transmittance of the light diffusing portion 41 is 90% or more by the regulations of JIS K7361-1. If the total light transmittance is 90% or more, the sufficient transparency is obtained. As shown in FIG. 4(A), in the light diffusing portion 41, an area of the light emission end face 41a becomes small, the area of the light incidence end face 41b becomes large, and the area of a horizontal cross section becomes gradually large toward the opposite side to the base material 39 from the base material 39 side. That is, the light diffusing portion 41 has a so-called reverse taper shape, when seen from the base material 39 side.

The light diffusing portion 41 is a portion contributing to the transmitting of the light in the light diffusing touch panel 7. That is, the light which is incident to the light diffusing portion 41, is totally reflected by a tapered-shaped side face 41c of the light diffusing portion 41, and is guided in the state of being almost confined in the inside of the light diffusing portion 41, and is emitted. Since the light diffusing portions 41 are formed in the region other than the formation region of the black layer 40 among one face 39a of the base material 39, the light diffusing portions 41 are randomly arranged when seen from the viewing side, as shown in FIG. 4(B).

Furthermore, it is preferable that an refractive index of the base material 39 is almost the same as the refractive index of the light diffusing portion 41. The reason thereof is as follows. For example, if the refractive index of the base material 39 is greatly different from the refractive index of the light diffusing portion 41, when the light which is incident from the light incidence end face 41b is emitted from the light diffusing portion 41, a failure that a desired viewing angle is not obtained, or that a light amount of the emitted light is reduced, may occur since the unnecessary refraction or the unnecessary reflection of the light occurs on the interface between the light diffusing portion 41 and the base material 39.

In the light diffusing touch panel 7, as shown in FIG. 2, since the base material 39 is arranged so as to face the viewing side, among two truncated circular cone-shaped counter faces of the light diffusing portion 41, the face of which the area is small becomes the light emission end face 41a, and the face of which the area is large becomes the light incidence end face 41b. Moreover, an inclination angle (angle which is formed by the light emission end face 41a and the side face 41c) of the side face 41c of the light diffusing portion 41, is approximately 80 degrees as an example. However, the inclination angle of the side face 41c of the light diffusing portion 41 is not particularly limited, as long as the angle enables to sufficiently diffuse the incident light in a case of emitting the light from the light diffusing touch panel 7.

In the case of the first embodiment, since the air is interposed between the adjacent light diffusing portions 41, for example, if the light diffusing portion 41 is formed of the transparent acryl resin, the side face 41c of the light diffusing portion 41 becomes the interface between the transparent acryl resin and the air. Here, even when the vicinity of the light diffusing portion 41 is filled with other materials having the low refractive index, a refractive index difference of the interface between the inside and the outside of the light diffusing portion 41 in the case that the air is present, becomes the maximum, in comparison with the case that any type of the material having the low refractive index is present on the outside. Accordingly, by a rule of Snell, a critical angle becomes the smallest angle in the configuration of the first embodiment, and an incidence angle range where the light is totally reflected by the side face 41c of the light diffusing portion 41, becomes most wide. As a result, a loss of the light is suppressed more, and high luminance can be obtained.

The conductive film 42 is a thin film which is formed on the other face 39b of the base material and is made up of a transparent conductive material such as ITO (Indium Tin Oxide) or IZO (Indium Zinc Oxide).

Furthermore, the conductive film 42 is not limited thereto, and may be formed of the thin film which is made up of the above transparent conductive material, on the base material where reflection prevention, a hard coat, a polarizing filter, electrification prevention, an antiglare treatment, an antifouling treatment or the like is carried out.

In the light diffusing touch panel 7, the base material 39 forms a dielectric layer, the black layer 40 forms one (referred to as “a first conductive film,” hereinafter) of a pair of conductive films, and the conductive film 42 forms the other (referred to as “a second conductive film,” hereinafter) of the pair of conductive films. The first conductive film (black layer 40) and the second conductive film (conductive film 42) are arranged so as to form a simple matrix structure. Therefore, if a finger touches the second conductive film (conductive film 42), capacitance of the vicinity thereof is changed, and it is possible to detect a position at multipoint. Furthermore, as a touch panel system, a capacitance system is exemplified, but the first embodiment is not limited thereto.

FIG. 5 is a schematic diagram illustrating an operation of a touch panel.

As shown in FIG. 5(b), in a circuit of a touch panel having coordinates which are made up of wires (conductive portions) A, B and C, and wires (conductive portions) (1), (2), (3) and (4), for example, a pulse signal is input in order of the wires A, B and C.

If the finger simultaneously touches two points of a point A-(1) (intersection point of the wire A and the wire (1)) and a point C-(3) (intersection point of the wire C and the wire (3)), the relative large capacitance is formed at the intersection point of the two points.

Here, detection circuits shown in FIG. 5(b) are arranged at ends of the wires (1), (2), (3) and (4), and a potential change of a detection line is detected while synchronizing with a clock signal.

As shown in FIG. 5(a) and FIG. 5(c), for a period of t1 to t2 in which the pulse is input to the wire A, since the pulse is detected in the wire (1), the wire A is identified from the timing in which the pulse is input, the wire (1) is identified form the position in which the pulse is input, and the touch of the point A-(1) is recognized.

Next, as shown in FIG. 5(a) and FIG. 5(c), for the period of t2 to t3 in which the pulse is input to the wire B, since the pulse is not detected in the wires (1) to (4), it is found out that the wire B is not touched.

Subsequently, as shown in FIG. 5(a) and FIG. 5(c), for the period of t3 to t4 in which the pulse is input to the wire C, since the pulse is detected in the wire (3), the wire C is identified from the timing in which the pulse is input, the wire (3) is identified form the position in which the pulse is input, and the touch of the point C-(3) is recognized.

That is, by arranging a means for sequentially inputting the pulse in any one of XY, and arranging a means for detecting the pulse in the other, a circuit in which the means is operated according to a synchronization signal, is formed. Hereby, the circuit functions as a touch panel.

Hereinafter, a specific configuration of the liquid crystal panel 4 will be described.

Here, a transmission type liquid crystal panel of an active matrix system is described as an example, but the liquid crystal panel which is applicable to the present invention, is not limited to the transmission type liquid crystal panel of the active matrix system. For example, the liquid crystal panel which is applicable to the present invention, may be a transflective type (dual-purpose type of transmission and reflection) liquid crystal panel, or a reflection type liquid crystal panel, and furthermore, may be a liquid crystal panel of a simple matrix system in which each pixel does not include a thin film transistor (abbreviated to a TFT, hereinafter) for switching.

FIG. 3 is a longitudinal cross-sectional view of the liquid crystal panel 4.

As shown in FIG. 3, the liquid crystal panel 4 has a TFT substrate 9 as a switching element substrate, a color filter substrate 10 that is arranged to be counter to the TFT substrate 9, and a liquid crystal layer 11 that is pinched between the TFT substrate 9 and the color filter substrate 10. The liquid crystal layer 11 is sealed within a space which is hardened by the TFT substrate 9, the color filter substrate 10, and a frame-shaped seal member (not shown) of bonding the TFT substrate 9 and the color filter substrate 10 at the predetermined gap. For example, the liquid crystal panel 4 of the first embodiment performs the display in a VA (Vertical Alignment) mode, and the vertical alignment liquid crystal of which dielectric anisotropy is negative, is used in the liquid crystal layer 11. Between the TFT substrate 9 and the color filter substrate 10, a globe-shaped spacer 12 for constantly retaining the gap between the substrates, is arranged. Furthermore, the display mode is not limited to the VA mode. A TN (Twisted Nematic) mode, a STN (Super Twisted Nematic) mode, an IPS (In-Plane Switching) mode, or the like can be used.

In the TFT substrate 9, a pixel (not shown) is a minimum unit region of the display, and a plurality of pixels are arranged in a matrix shape. In the TFT substrate 9, a plurality of source bus lines (not shown) are formed so as to extend in parallel with each other, and a plurality of gate bus lines (not shown) are formed so as to extend in parallel with each other and to be orthogonal to the plurality of source bus lines. Accordingly, on the TFT substrate 9, the plurality of source bus lines and the plurality of gate bus lines are formed in a frame shape, and a rectangular-shaped region which is sectioned by the adjacent source bus lines and the adjacent gate bus lines, forms one pixel. The source bus line is connected to a source electrode of the TFT described later, and the gate bus line is connected to a gate electrode of the TFT.

On the face of the liquid crystal layer 11 side of a transparent substrate 14 configuring the TFT substrate 9, a TFT 19 having a semiconductor layer 15, a gate electrode 16, a source electrode 17, a drain electrode 18 or the like, is formed. For example, a glass substrate can be used in the transparent substrate 14. On the transparent substrate 14, for example, the semiconductor layer 15 which is made up of a semiconductor material such as CGS (Continuous Grain Silicon), LPS (Low-temperature Poly-Silicon), or α-Si (Amorphous Silicon), is formed. Moreover, on the transparent substrate 14, a gate insulating film 20 is formed so as to cover the semiconductor layer 15. For example, a silicon oxide film, a silicon nitride film, or a stacked film thereof is used as a material of the gate insulating film 20.

On the gate insulating film 20, the gate electrode 16 is formed so as to be counter to the semiconductor layer 15. For example, a stacked film of W (tungsten) and TaN (tantalum nitride), Mo (molybdenum), Ti (titanium), or Al (aluminum) is used as a material of the gate electrode 16.

On the gate insulating film 20, a first insulating interlayer 21 is formed so as to cover the gate electrode 16. For example, the silicon oxide film, the silicon nitride film, or the stacked film thereof is used as a material of the first insulating interlayer 21. On the first insulating interlayer 21, the source electrode 17 and the drain electrode 18 are formed. The source electrode 17 is connected to a source region of the semiconductor layer 15 through a contact hole 22 penetrating the first insulating interlayer 21 and the gate insulating film 20. Similarly, the drain electrode 18 is connected to a drain region of the semiconductor layer 15 through a contact hole 23 penetrating the first insulating interlayer 21 and the gate insulating film 20.

As a material of the source electrode 17 and the drain electrode 18, the same conductive material as the gate electrode 16 described above, is used. On the first insulating interlayer 21, a second insulating interlayer 24 is formed so as to cover the source electrode 17 and the drain electrode 18.

As a material of the second insulating interlayer 24, the same material as the first insulating interlayer 21 described above, or an organic insulating material is used.

On the second insulating interlayer 24, a pixel electrode 25 is formed. The pixel electrode 25 is connected to the drain electrode 18 through a contact hole 26 penetrating the second insulating interlayer 24. Accordingly, the pixel electrode 25 as an electrode for relaying the drain electrode 18, is connected to the drain region of the semiconductor layer 15.

As a material of the pixel electrode 25, for example, the transparent conductive material such as ITO (Indium Tin Oxide) or IZO (Indium Zinc Oxide), is used.

By the configuration, a scan signal is supplied through the gate bus line, and an image signal which is supplied to the source electrode 17 through the source bus line in the case that the TFT 19 is in an ON state, is supplied to the pixel electrode 25 by way of the semiconductor layer 15 and the drain electrode 18. Moreover, an alignment film 27 is formed so as to cover the pixel electrode 25, on the whole face of the second insulating interlayer 24. The alignment film 27 has alignment regulation power to vertically align liquid crystal molecules configuring the liquid crystal layer 11. Furthermore, the shape of the TFT may be a bottom gate type TFT shown in FIG. 3, or may be a top gate type TFT.

On the other hand, on the face of the liquid crystal layer 11 side of a transparent substrate 29 configuring the color filter substrate 10, a black matrix 30, a color filter 31, a planarizing layer 32, a counter electrode 33, an alignment film 34 are sequentially formed.

The black matrix 30 has a function of blocking the transmitting of the light in the region between the pixels, and is formed of the metal such as Cr (chrome) or a multilayer film of Cr and Cr oxide, or photoresist of diffusing carbon particles into the photosensitive resin.

In the color filter 31, pigments of the respective colors of red (R), green (G) and blue (B), are included, and one color filter 31 is arranged to be counter to any one of R, G and B in one pixel electrode 25 on the TFT substrate 9.

The planarizing layer 32 is configured of the insulating film covering the black matrix 30 and the color filter 31, and has a function of relieving and planarizing a step difference which may be caused by the black matrix 30 and the color filter 31.

The counter electrode 33 is formed on the planarizing layer 32. As a material of the counter electrode 33, the same transparent conductive material as the pixel electrode 25, is used.

Moreover, on the whole face of the counter electrode 33, the alignment film 34 having the vertical alignment regulation power, is formed.

The color filter 31 may have a multicolor configuration of three colors of R, G and B, or more.

As shown in FIG. 2, the backlight 2 has a light-emitting diode, a light source 36 such as a cold-cathode tube, and a light guide 37 that emits the light toward the liquid crystal panel 4 using the inside reflection of the light which is emitted from the light source 36. The backlight 2 may be an edge light type in which the light source is arranged on the end face of a light guide body, or may be a directly under type in which the light source is arranged directly under the light guide body. It is preferable that a so-called directivity backlight which is a backlight having the directivity of controlling a light emission direction is used in the backlight 2 used in the first embodiment. The blur is reduced by using the directivity backlight which makes the collimated light or the almost collimated light be incident to the light diffusing portion of the light diffusing touch panel 7 described later, and furthermore, it is possible enhance usage efficiency of the light. The above directivity backlight can be realized by optimizing the shape or the arrangement of a reflection pattern which is formed within the light guide 37. Additionally, between the backlight 2 and the liquid crystal panel 4, the first polarizing plate 3 functioning as a polarizer is arranged. Moreover, between the liquid crystal panel 4 and a viewing angle widening film 7, the second polarizing plate 5 functioning as an analyzer is arranged.

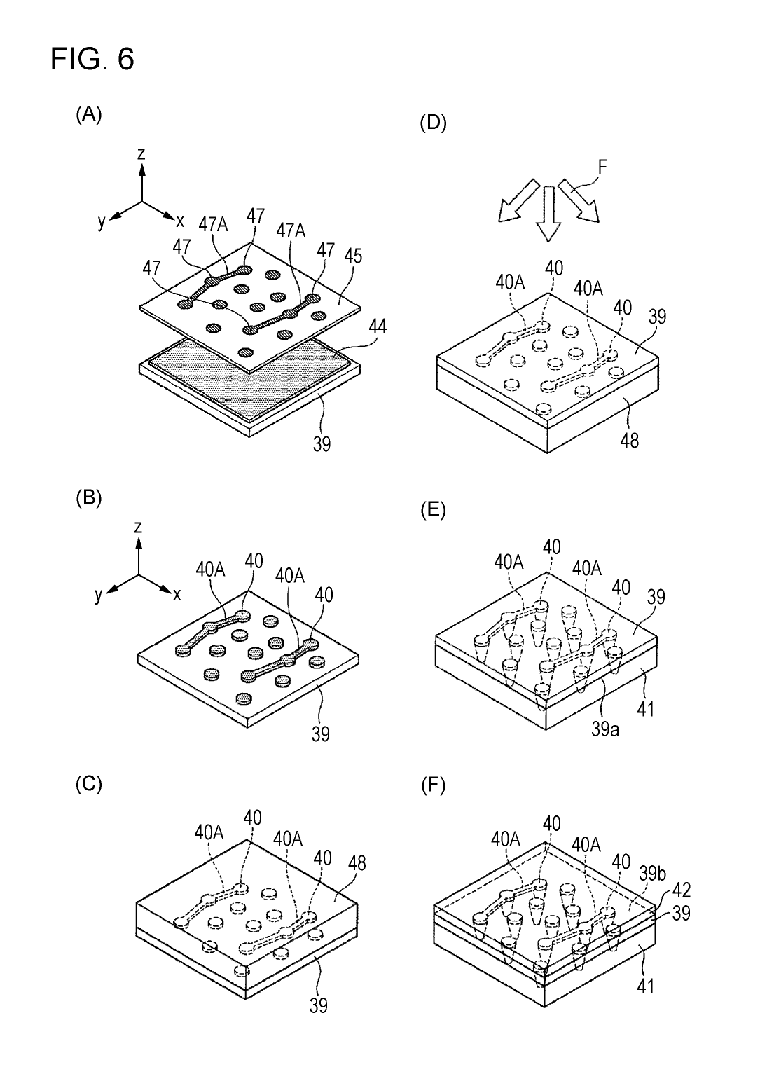

Next, a manufacturing method of the liquid crystal display device 1 of the above configuration, will be described using FIG. 6 to FIG. 8.

Hereinafter, a manufacturing step of the light diffusing touch panel 7 will be mainly described.

If an outline of the manufacturing step of the liquid crystal display body 6 will be described previously, first, the TFT substrate 9 and the color filter substrate 10 are manufactured, respectively. Thereafter, the face of the side where the TFT 19 is formed in the TFT substrate 9, and the face of the side where the color filter 31 is formed in the color filter substrate 10, are arranged to be counter to each other, and the TFT substrate 9 and the color filter substrate 10 are boned through the seal member. Thereafter, the liquid crystal is injected into the space which is hardened by the TFT substrate 9, the color filter substrate 10 and the seal member. Therefore, on both faces of the liquid crystal panel 4 which are manufactured as described above, each of the first polarizing plate 3 and the second polarizing plate 4 are bonded using an optical adhesive. By way of the above steps, the liquid crystal display body 6 is completed.

Furthermore, since a well-known method in the past is used in the manufacturing method of the TFT substrate 9 and the color filter substrate 10, the description thereof will be omitted.

First, as shown in FIG. 6(A), for example, the base material 39 of triacetyl cellulose of which the thickness is 100 μm, is prepared at the angle of 10 cm. For example, on one face of the base material 39, an ITO film of which the thickness is approximately 100 nm, is formed.

Next, black negative resist containing carbon as a black layer material of which the film thickness is 150 nm, is coated onto the upper face of the ITO film, and a coating film 44 is formed.

Thereafter, the base material 39 where the coating film 44 is formed, is mounted on a hot plate, and for example, prebake of the coating film 44 is performed at a temperature of 90° C. Hereby, a solvent in the black negative resist is volatilized.

Next, using an exposure device, the coating film 44 is irradiated with the light, through a photomask 45 where a plurality of opening portions (light shielding pattern) 47 forming the round shape or the elliptical shape are arranged in random, and the exposure is performed.

At this time, the exposure device using a mixed line of an i line having a wavelength of 365 nm, an h line having the wavelength of 404 nm, and a g line having the wavelength of 436 nm, is used. An exposure amount is assumed to be 100 mJ/cm².

Furthermore, along the y axis direction of the photomask 45, the opening portions 47 forming the round shape or the elliptical shape are connected to each other by opening portions 47A forming the line shape (belt shape). Still more, the opening portions 47A are formed in parallel at the predetermined gap, so as to form the line shape (belt shape), along the y axis direction of the photomask 45.

In the case of the first embodiment, the exposure of transparent negative resist is performed using the black layer 40 as a mask in the following step, and the position of the light shielding portion (a portion other than the opening portions 47 and 47A) of the photomask 45 corresponds to the formation position of the light diffusing portion 41, in order to form the light diffusing portion 41.

Furthermore, it is preferable that the average gap of the opening portions 47 and 47A of the photomask 45, is smaller than the gap (pitch) between the pixels of the liquid crystal panel 4. Hereby, since at least one light diffusing portion 41 is formed within the pixel, for example, when combined with the liquid crystal panel which is used in a mobile apparatus and the pixel pitch thereof is small, it is possible to improve the display quality.

After the exposure is performed using the photomask 45, developing of the coating film 44 which is made up of the black negative resist, is performed using a dedicated developing solution, and the developed coating film 44 is dried at 100° C. As shown in FIG. 6(B), on one face 39a of the base material 39, the black layer 40 forming the round shape or the elliptical shape, is formed. Moreover, as shown in FIG. 6(B), the black layers 40 forming the round shape or the elliptical shape, are formed in parallel at the predetermined gap, so as to form the line shape (belt shape), along the y axis direction of the base material 39, and are connected to each other by the conductive portions 40A which are made up of the same material as the black layer 40. Thereafter, the ITO film is patterned by etching, and thereby, the ITO film for securing the conductivity is formed between the black layer 40 and the base material 39.

The region other than the formation region of the black layer 40 among one face 39a of the base material 39, corresponds to the formation region of the light diffusing portion 41 of the following step.

In the first embodiment, the black layer 40 is formed by a photo lithography method using the black negative resist, but instead of the configuration, if the photomask is used by reversing the opening portions 47 and 47A, and the light shielding portion in the first embodiment, positive resist can be used. Alternatively, the black layer 40 may be formed using an evaporation method or a printing method.

Next, as shown in FIG. 6(C), using a spin coat method, the transparent negative resist which is made up of the acryl resin as a material of the light diffusing portion, is coated onto the upper face of the black layer 40, and for example, a coating film 48 of which the film thickness is 25 μm, is formed.

Subsequently, the base material 39 where the coating film 48 is formed, is mounted on the hot plate, and for example, the prebake of the coating film 48 is performed at the temperature of 95° C. Hereby, the solvent in the transparent negative resist is volatilized.

Next, as shown in FIG. 6(D), the base material 39 is reversed upward and downward, and the coating film 48 is irradiated with a diffused light F from the base material 39 using the black layer 40 as a mask, and the exposure is performed.

At this time, the exposure device using the mixed line of the i line having the wavelength of 365 nm, the h line having the wavelength of 404 nm, and the g line having the wavelength of 436 nm, is used. The exposure amount is assumed to be 500 mJ/cm². Moreover, for example, as a means for irradiating the base material with the parallel light which is emitted from the exposure device as a diffused light F, a diffusing plate of approximately Hayes 50 degrees is favorable if be arranged on an optical path of the light which is emitted from the exposure device.

Thereafter, the base material 39 where the coating film 48 is formed, is mounted on the hot plate, and for example, post exposure bake (PEB) of the coating film 48 is performed at the temperature of 95° C.

Subsequently, the developing of the coating film 48 which is made up of the transparent negative resist, is performed using the dedicated developing solution, and the developed coating film 48 is post baked at 100° C. As shown in FIG. 6(E), the light diffusing portion 41 is formed on one face 39a of the base material 39.

Next, on the other face 39b of the base material 39, the conductive film 42 is formed.

By a sputtering method, a thin film which is made up of the transparent conductive material such as ITO or IZO is formed on the other face 39b of the base material 39, or the thin film which is made up of the above transparent conductive material is formed on a transparent base material, and by sticking the thin film to the other face 39b of the base material, the conductive film 42 is arranged.

Here, the case that the conductive film 42 is formed on the other face 39b of the base material 39 after the light diffusing portion 41 is formed on one face 39a of the base material 39, is exemplified, but the present invention is not limited thereto. In the present invention, using the base material where the conductive film is formed in advance, the black layer and the light diffusing portion may be formed on the base material.

By way of the steps shown in FIG. 6, the light diffusing touch panel 7 of the first embodiment is completed. It is preferable that the total light transmittance of the light diffusing touch panel 7 is 90% or more. If the total light transmittance is 90% or more, the sufficient transparency is obtained, and optical performance which is asked in the viewing angle widening member can be sufficiently exhibited. The total light transmittance is determined by the regulations of JIS K7361-1.

The case that the exposure is performed by reversing the base material 39 upward and downward, is described, but the base material 39 may not be reversed upward and downward, and it is favorable as long as a manufacturing device is configured so as to perform the exposure from the base material 39 side.

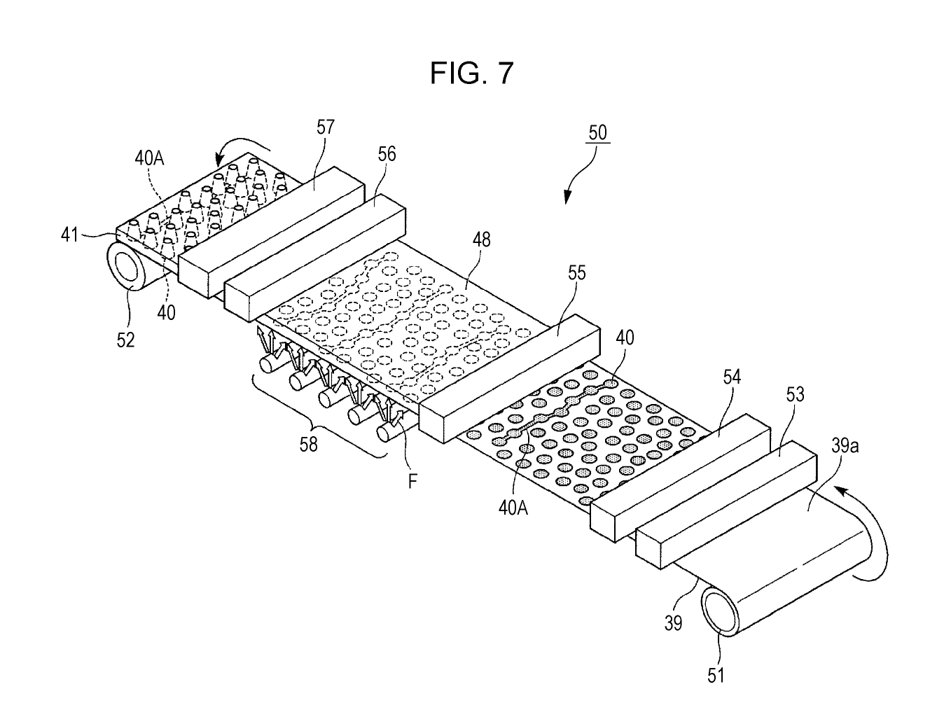

FIG. 7 is a schematic configuration diagram illustrating an example of the manufacturing device for the light diffusing touch panel 7.

A manufacturing device 50 shown in FIG. 7, transports the base material 39 of the long length by a roll to roll system, and performs various types of treatments therebetween. Moreover, the manufacturing device 50 uses the printing method in the formation of the black layer 40, but as described above, it is possible to form the black layer 40 using the photo lithography method.

A sending roller 51 sending the base material 39 is arranged at one end of the manufacturing device 50, and a winding roller 52 winding the base material 39 is arranged at the other end. The base material 39 is configured to move toward the winding roller 52 side from the sending roller 51 side. Above the base material 39, a printing device 53, a first drying device 54, a coating device 55, a developing device 56, and a second drying device 57 are sequentially arranged toward the winding roller 52 side from the sending roller 51 side. Below the base material 39, an exposure device 58 is arranged.

The printing device 53 is a device for printing the black layer 40 and the conductive portion 40A on the base material 39.

The first drying device 54 is a device for drying the black layer 40 and the conductive portion 40A which are formed by the printing.

The coating device 55 is a device for coating the transparent negative resist onto the black layer 40 and the conductive portion 40A.

The developing device 56 is a device for developing the transparent negative resist after the exposure by the developing solution.

The second drying device 57 is a device for drying the base material 39 where the light diffusing portion 41 which is made up of the transparent resist after the developing is formed.

Thereafter, the base material 39 where the light diffusing portion 41 is formed, is bonded to the transparent substrate where the thin film which is made up of the transparent conductive material is formed, and the conductive film 42 may be formed on the other face 39b of the base material.

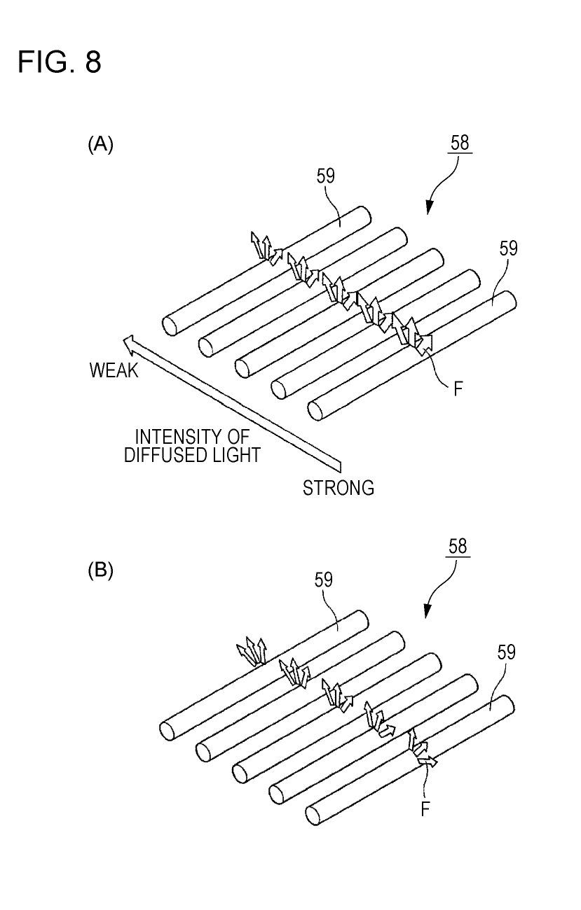

The exposure device 58 is a device for performing the exposure of the coating film 48 of the transparent negative resist from the base material 39 side. FIG. 8(A) and FIG. 8(B) are diagrams illustrating a portion by taking out only the portion of the exposure device 58 in the manufacturing device 50. The exposure device 58 includes a plurality of light sources 59, and as shown in FIG. 8(A), in association with progress of the base material 39, the exposure device 58 may change intensity of the diffused light F such that the intensity of the diffused light F becomes gradually weak from each light source 59. Alternatively, as shown in FIG. 8(B), in association with the progress of the base material 39, the exposure device 58 may change an emission angle of the diffused light F such that the emission angle of the diffused light F is gradually changed from each light source 59. By using the exposure device 58, it is possible to control the inclination angle of the side face 41c of the light diffusing portion 41 at an desired angle.

In the above examples, the liquid-shaped resist is coated at the time of forming the black layer 40 and the light diffusing layer 41, but instead of the configuration, the film-shaped resist may be attached to one face 39a of the base material 39.

Finally, as shown in FIG. 2, the completed light diffusing touch panel 7 is attached to the liquid crystal display body 6 using the optical adhesive, in the state that the base material 39 where the conductive film 42 is formed faces the viewing side, and the light diffusing portion 41 is counter to the second polarizing plate 5.

By the above steps, the liquid crystal display device 1 of the first embodiment is completed.

In the light diffusing touch panel 7 of the first embodiment, the base material 39 forms the dielectric layer, the black layer 40 forms the first conductive film, and the conductive film 42 forms the second conductive film. That is, in the light diffusing touch panel 7, a stacked body which is made up of the black layer 40, the base material 39 and the conductive film 42, functions as a touch panel. In this manner, since the base material 39 serves as a dielectric layer, and the black layer 40 serves as a light absorbing layer and a first conductive film of the touch panel, it is possible to make the light diffusing touch panel 7 be a thin type, and it is possible to manufacture the light diffusing touch panel 7 at a low cost.

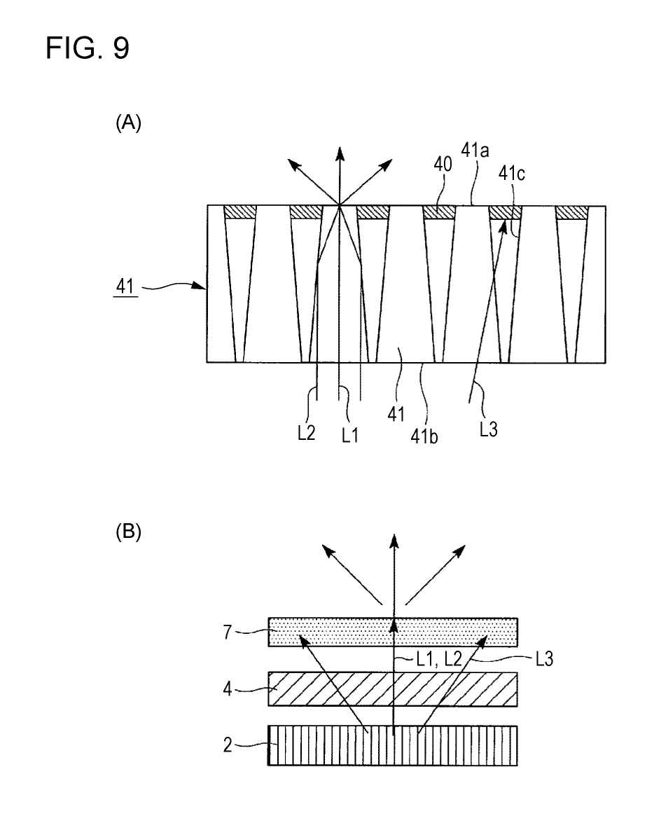

Here, an viewing angle widening effect which is included in the light diffusing touch panel 7 of the first embodiment, will be described using FIG. 9(A) and Fig. (B).

As shown in FIG. 9(A), among the light which is emitted from the liquid crystal display body 6, and is incident to the light diffusing touch panel 7, a light L1 which is incident almost vertically to the light incidence end face 41b in the vicinity of a center of the light diffusing portion 41, transmits the light diffusing portion 41 as it is by going straight without being totally reflected by the side face 41c of the light diffusing portion 41. Moreover, a light L2 which is incident almost vertically to the light incidence end face 41b in a peripheral portion of the light diffusing portion 41, is totally reflected by the side face 41c of the light diffusing portion 41 since the light L2 is incident to the side face 41c of the light diffusing portion at the incidence angle which is greater than the critical angle. Thereafter, the totally reflected light is refracted by the light emission end face 41a of the light diffusing portion 41, and is emitted in a direction forming a large angle with respect to a normal direction of the light emission end face 41a. On the other hand, a light L3 which is incident obliquely to the light incidence end face 41b of the light diffusing portion 41, transmits the side face 41c of the light diffusing portion 41 since the light L3 is incident to the side face 41c of the light diffusing portion 41 at the incidence angle which is smaller than the critical angle, and is absorbed by the light absorbing layer 40.

As shown in FIG. 9(B), by the above operations, the light L1 and the light L2 which are incident almost vertically to the light diffusing touch panel 7, are emitted from the light diffusing touch panel 7 in the state of widening the angle distribution than that before the incidence to the light diffusing touch panel 7. Accordingly, the observer can visually confirm the favorable display even in the case of tilting the eyes from a front side direction (normal direction) of the liquid crystal display body 6. Moreover, the light L3 which is incident obliquely to the light diffusing touch panel 7, is the light which obliquely transmits the liquid crystal panel 4, and is the light of which retardation is different from the desired retardation, so to speak, the light which is a factor of degradation in contrast of the display. The light diffusing touch panel 7 of the first embodiment can enhance the contrast of the display by cutting such the light by the light absorbing layer 40.

In general, when patterns having regularity such as stripes or frames are superposed, it is found out that an interference fringe pattern (moire) is visually confirmed if periods of the respective patterns are slightly deviated. For example, if the viewing angle widening member where the plurality of light diffusing portions are arranged in the matrix shape, and the liquid crystal panel where the plurality of pixels are arranged in the matrix shape are superposed, the moire is generated between a period pattern depending on the light diffusing portion of the viewing angle widening member, and the period pattern depending on the pixel of the liquid crystal panel, and the display quality may be lowered. In contrast, according to the liquid crystal display device 1 of the first embodiment, the plurality of black layers 40 are planarly arranged in random, and as a result, the light diffusing portion 41 which is formed in the region other than the formation region of the black layer 40 among one face 39a of the base material 39, are planarly arranged in random, and thus, the moire is not generated depending on the interference between the regular arrangements of the pixels of the liquid crystal panel 4, and the display quality can be maintained.

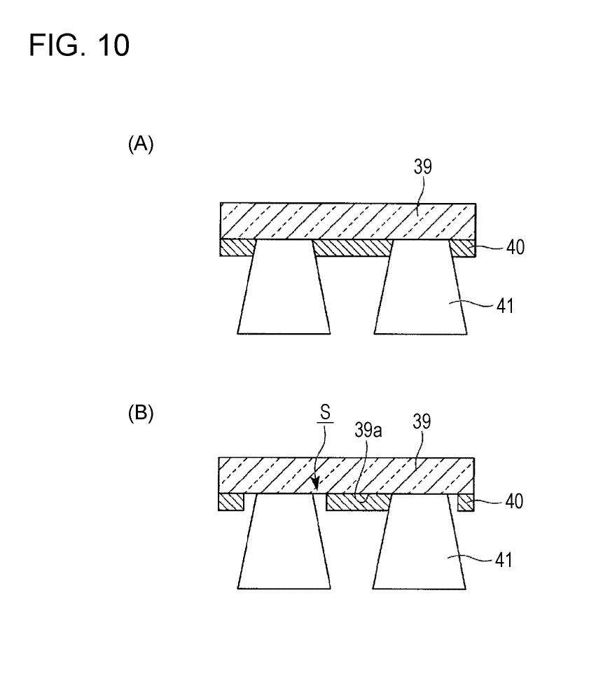

Moreover, in the step of forming the light diffusing portion 41, if the irradiation of the light is performed through the photomask from the side of the coating film 48 which is made up of the transparent negative resist, the alignment adjustment of the base material 39 where the black layer 40 of the minute size is formed and the photomask, is very difficult, and the occurrence of the deviation is not avoided. As a result, as shown in FIG. 10(B), a space S is arranged between the light diffusing portion 41 and the black layer 40, and the light is leaked out from the space S, and thereby, the contrast may be lowered.

In contrast, in the case of the first embodiment, since the irradiation of the light is performed from the rear face side of the base material 39 using the black layer 40 as a mask, the light diffusing portion 41 is formed in the region other than the formation region of the black layer 40 among one face 39a of the base material 39. As a result, the light diffusing portion 41 and the black layer 40 are in the state of adhering closely to each other, and the space is not arranged therebetween, and the contrast can be maintain.

In addition, when the black layer 40 is not arranged in the base material 39, the external light which is incident to the light diffusing touch panel 7 is also scattered. In addition to the occurrence of the external scattering and the lowering of the viewability at a bright place, the contrast may be lowered by generating “black floating” of the case that the black looks whitish at the time of the black display, and it is not possible to perform the suitable observation of the image. In order to prevent such the problems, the black layer 40 is arranged in the base material 39.

### Second Embodiment

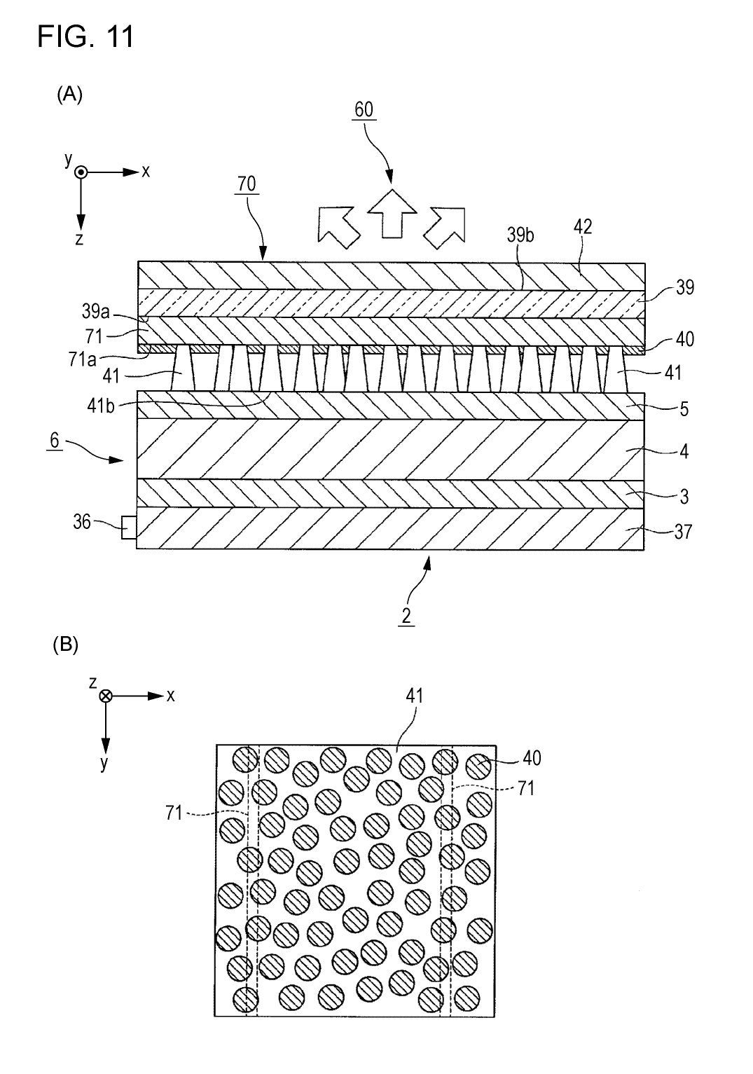

FIG. 11 is a diagram illustrating a liquid crystal display device according to a second embodiment. (A) is a longitudinal cross-sectional view, and (B) is a plan view which is seen from the viewing side. Furthermore, FIG. 11(B) shows the state of being cut by the interface between a conductive film 71 and the black layer 40. In FIG. 11, the same signs are attached to the same components as the liquid crystal display device 1 shown in FIG. 2, and the description thereof will be omitted.

In a liquid crystal display device 60 according to the second embodiment, a point which is different from the liquid crystal display device 1 according to the first embodiment, is the point in which a light diffusing touch panel 70 includes the conductive film (first conductive film) 71, separately from the black layer 40, as shown in FIG. 11(A). That is, the light diffusing touch panel 70 is schematically configured of the base material 39, the conductive film (first conductive film) 71 that is formed on one face 39a of the base material 39, the plurality of black layers 40 (light absorbing layers) that are formed on an opposite face (one face) 71a of the first conductive film 71 to the base material 39, the plurality of light diffusing portions 41 that are formed in the region other than the formation region of the black layer 40 among one face 71a of the first conductive film 71, and the conductive film (second conductive film) 42 that is formed on the other face (face of the viewing side) 39b of the base material 39.

The first conductive film 71 is a thin film which is formed on one face 39a of the base material 39 and is made up of the transparent conductive material such as ITO or IZO.

Moreover, the first conductive film 71 is not necessary to be arranged on the whole face of one face 39a of the base material 39, and for example, as shown in FIG. 11(B), in both of edge portions along the y axis direction of one face 39a of the base material 39, it is favorable as long as the first conductive film 71 is formed so as to form the line shape (belt shape) when seen from the viewing side. That is, the first conductive film 71 has the conductivity, in both of the edge portions along the y axis direction of the base material 39.

In the light diffusing touch panel 60 of the second embodiment, the stacked body which is made up of the first conductive film 71, the base material 39 forming the dielectric layer, and the conductive film 42 forming the second conductive film, functions as a touch panel. The first conductive film 71 and the second conductive film (conductive film 42) are arranged so as to form the simple matrix structure. Therefore, if the finger touches the second conductive film (conductive film 42), the capacitance of the vicinity thereof is changed, and it is possible to detect the position at multipoint. Here, as a touch panel system, the capacitance system is exemplified, but the second embodiment is not limited thereto.

Moreover, since the base material 39 serves as a dielectric layer, and the first conductive film 71 is formed in both of the edge portions along the y axis direction of one face 39a of the base material 39, it is possible to make the light diffusing touch panel 60 be a thin type, and it is possible to manufacture the light diffusing touch panel 60 at a low cost. Additionally, in the second embodiment, the black layer 40 may not have the conductivity in the same manner as the first embodiment.

### Third Embodiment

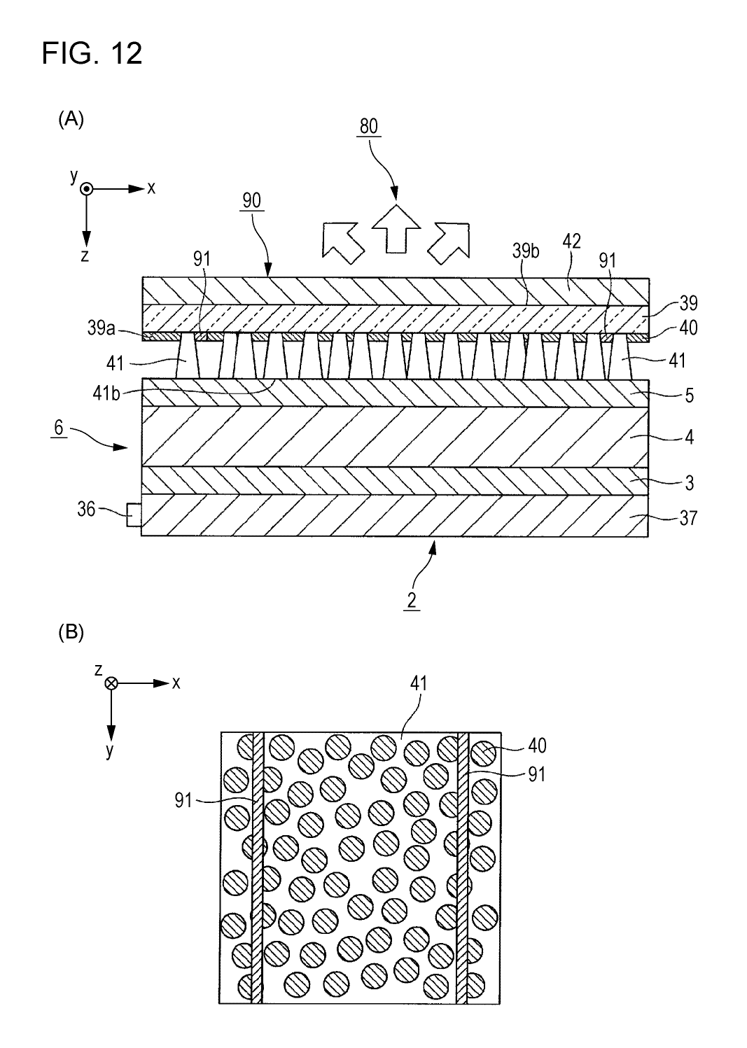

FIG. 12 is a diagram illustrating a liquid crystal display device according to a third embodiment. (A) is a longitudinal cross-sectional view, and (B) is a plan view which is seen from the viewing side. Furthermore, FIG. 12(B) shows the state of being cut by the interface between the base material 39 and the black layer 40. In FIG. 12, the same signs are attached to the same components as the liquid crystal display device 1 shown in FIG. 2, and the description thereof will be omitted.

In a liquid crystal display device 80 according to the third embodiment, the point which is different from the liquid crystal display device 1 according to the first embodiment, is the point in which a light diffusing touch panel 90 includes a conductive film (first conductive film) 91, separately from the black layer 40, as shown in FIG. 12(A). That is, the light diffusing touch panel 90 is schematically configured of the base material 39, the plurality of black layers 40 (light absorbing layers) that are formed on one face 39a of the base material 39, the conductive film (first conductive film) 91 that is formed in the region other than the formation region of the black layer 40 among one face 39a of the base material 39, the plurality of light diffusing portions 41 that are formed in the region other than the formation region of the black layer 40 and the first conductive film 91 among one face 39a of the base material 39, and the conductive film (second conductive film) 42 that is formed on the other face 39b of the base material 39.

The first conductive film 91 is a thin film which is formed on the other face 39b of the base material 39 and is made up of the transparent conductive material such as ITO or IZO, or the material having no transparency such as the metal.

In the light diffusing touch panel 80 of the third embodiment, the stacked body which is made up of the first conductive film 91, the base material 39 forming the dielectric layer, and the conductive film 42 forming the second conductive film, functions as a touch panel. The first conductive film 91 and the second conductive film (conductive film 42) are arranged so as to form the simple matrix structure. Therefore, if the finger touches the second conductive film (conductive film 42), the capacitance of the vicinity thereof is changed, and it is possible to detect the position at multipoint. Furthermore, here, as a touch panel system, the capacitance system is exemplified, but the third embodiment is not limited thereto.

Moreover, since the base material 39 serves as a dielectric layer, and the first conductive film 91 is formed in the region other than the formation region of the black layer 40 among one face 39a of the base material 39, it is possible to make the light diffusing touch panel 80 be a thin type, and it is possible to manufacture the light diffusing touch panel 80 at a low cost.

### Fourth Embodiment

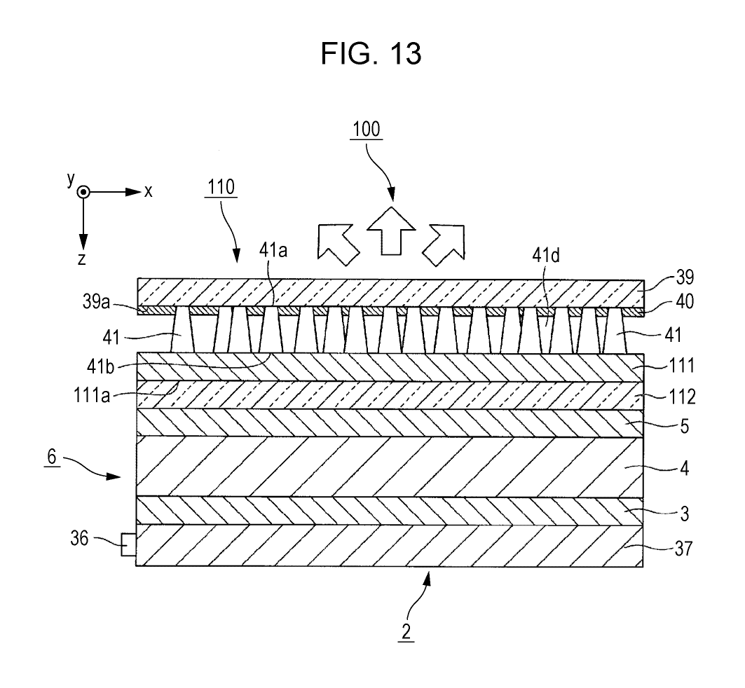

FIG. 13 is a longitudinal cross-sectional view illustrating a liquid crystal display device according to a fourth embodiment. In FIG. 13, the same signs are attached to the same components as the liquid crystal display device 1 shown in FIG. 2, and the description thereof will be omitted.

In a liquid crystal display device 100 according to the fourth embodiment, the point which is different from the liquid crystal display device 1 according to the first embodiment described above, is the point in which a light diffusing touch panel 110 includes a conductive film (second conductive film) 111 and a transparent base material 112, on the light incidence end face 41b side of the light diffusing portion 41, as shown in FIG. 13. That is, the light diffusing touch panel 110 is schematically configured of the base material 39, the plurality of black layers 40 (light absorbing layers) that are formed on one face 39a of the base material 39, the plurality of light diffusing portions 41 that are formed in the region other than the formation region of the black layer 40 among one face 39a of the base material 39, the second conductive film 111 that is formed on the light incidence end face 41b side of the light diffusing portion 41, and the transparent base material 112 that is arranged on a face 111a of the opposite side of the second conductive film 111 to the light diffusing portion 41.

The second conductive film 111 is a thin film which is formed on the light incidence end face 41b side of the light diffusing portion 41 and is made up of the transparent conductive material such as ITO or IZO.

As a transparent base material 112, the same material as the base material 39 is used.

In the light diffusing touch panel 110 of the fourth embodiment, the black layer 40 forms the first conductive film, and the air which is present in any one of the light diffusing portion 41 and an air gap 41d between the light diffusing portions 41, or the air which is present in both of the light diffusing portion 41 and the air gap 41d between the light diffusing portions 41, forms the dielectric layer. The stacked body that is made up of the black layer 40, the air which is present in the air gap 41d, and the second conductive film 111, functions as a touch panel. The first conductive film (black layer 40) and the second conductive film 111 are arranged so as to form the simple matrix structure. Therefore, if the finger touches the base material 39, in the vicinity thereof, the capacitance between the black layer 40 which is formed on one face 39a of the base material 39 and the second conductive film 111 is changed, and it is possible to detect the position at multipoint. Here, as a touch panel system, the capacitance system is exemplified, but the fourth embodiment is not limited thereto.

Moreover, in the light diffusing touch panel 110, the stacked body that is made up of the black layer 40, the air which is present in the air gap 41d between the light diffusing portions 41, and the second conductive film 111, functions as a touch panel. Since the black layer 40 serves as a first conductive film, and the air which is present in any one of the light diffusing portion 41 and the air gap 41d between the light diffusing portions 41, or the air which is present in both of the light diffusing portion 41 and the air gap 41d between the light diffusing portions 41 forms the dielectric layer, it is possible to make the light diffusing touch panel 110 be a thin type, and it is possible to manufacture the light diffusing touch panel 110 at a low cost.

### Fifth Embodiment

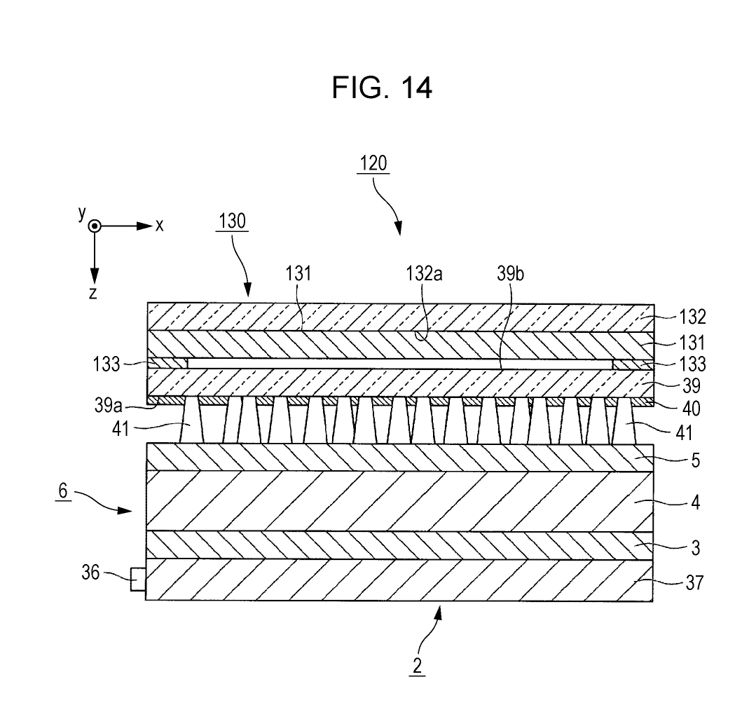

FIG. 14 is a longitudinal cross-sectional view illustrating a liquid crystal display device according to a fifth embodiment. In FIG. 14, the same signs are attached to the same components as the liquid crystal display device 1 shown in FIG. 2, and the description thereof will be omitted.

In a liquid crystal display device 120 according to the fifth embodiment, the point which is different from the liquid crystal display device 1 according to the first embodiment described above, is the point in which a light diffusing touch panel 130 includes a conductive film (second conductive film) 131 and a transparent base material 132, on the other face 39b side of the base material 39, as shown in FIG. 14. That is, the light diffusing touch panel 130 is schematically configured of the base material 39, the plurality of black layers 40 (light absorbing layers) that are formed on one face 39a of the base material 39, the plurality of light diffusing portions 41 that are formed in the region other than the formation region of the black layer 40 among one face 39a of the base material 39, the second conductive film 131 that is arranged on the on the other face 39b side of the base material 39 through an adhesive 133, and the transparent base material 132 that is arranged on a face 131a of the opposite side of the second conductive film 131 to the base material 39.

The second conductive film 131 is a thin film which is formed on one face 132a of the transparent base material 132 and is made up of the transparent conductive material such as ITO or IZO. That is, in the fifth embodiment, the transparent base material 132 where the second conductive film 131 is formed, is arranged on the other face 39b side of the base material 39, through the adhesive 133, in the state of directing the second conductive film 131 toward the base material 39 side. As a transparent base material 132, the same material as the base material 39 is used.

In the light diffusing touch panel 130 of the fifth embodiment, the base material 39 forms the dielectric layer, and the black layer 40 forms the first conductive film. That is, in the light diffusing touch panel 130, the stacked body that is made up of the black layer 40, the base material 39 and the second conductive film 131, functions as a touch panel. The first conductive film (black layer 40) and the second conductive film 131 are arranged so as to form the simple matrix structure. Therefore, if the finger touches the transparent base material 132, in the vicinity thereof, the capacitance of the second conductive film 131 which is formed on one face 132a of the transparent base material 132 is changed, and it is possible to detect the position at multipoint. Here, as a touch panel system, the capacitance system is exemplified, but the fifth embodiment is not limited thereto.

In this manner, since the base material 39 serves as a dielectric layer, and the black layer 40 serves as a light absorbing layer and a first conductive film of the touch panel, it is possible to make the light diffusing touch panel 130 be a thin type, and it is possible to manufacture the light diffusing touch panel 130 at a low cost. Moreover, in the fifth embodiment, since the black layer 40 and the light diffusing portion 41 are formed only on one face 39a side of the base material 39, and the second conductive film 131 is formed only on one face 132a side of the transparent base material 132, it is easy to manufacture.

### Sixth Embodiment

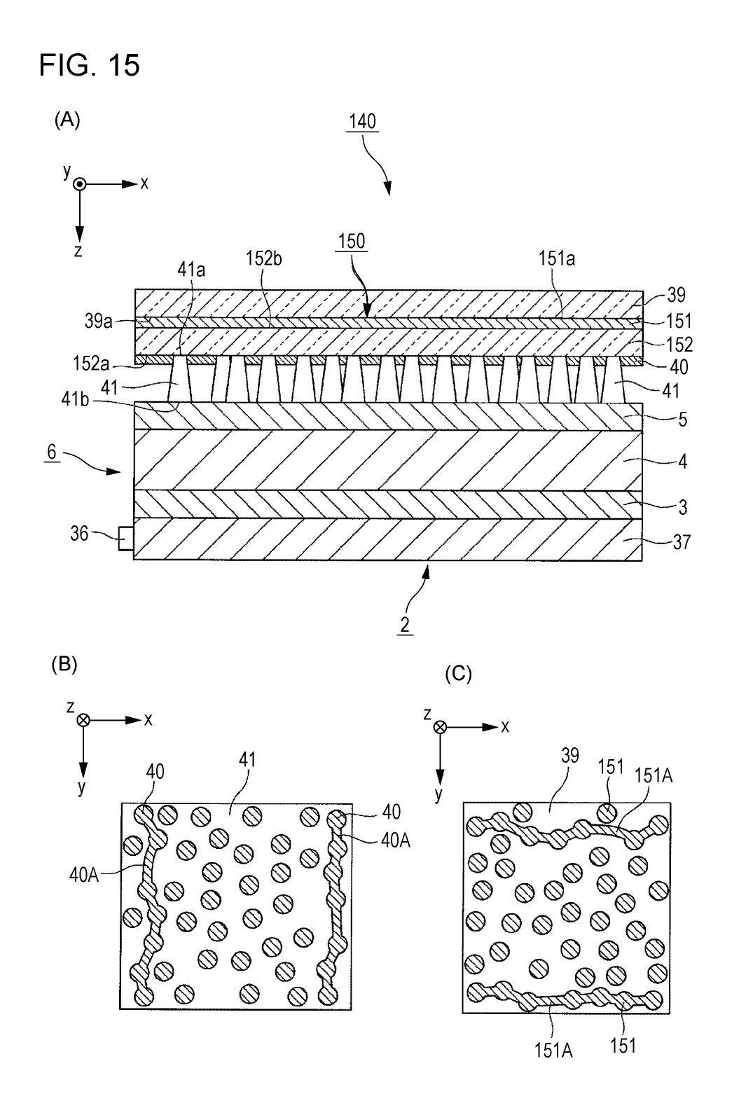

FIG. 15 is a diagram illustrating a liquid crystal display device according to a sixth embodiment. (A) is a longitudinal cross-sectional view, (B) is a plan view which is seen from the viewing side, and (C) is a plan vies which is seen from the viewing side. Furthermore, FIG. 15(B) shows the state of being cut by the interface between a dielectric body layer 152 and the black layer 40, and FIG. 15(C) shows the state of seeing a black layer 151 from the opposite side to the dielectric body layer 152.

In FIG. 15, the same signs are attached to the same components as the liquid crystal display device 1 shown in FIG. 2, and the description thereof will be omitted.

In a liquid crystal display device 140 according to the sixth embodiment, the point which is different from the liquid crystal display device 1 according to the first embodiment described above, is the point in which a light diffusing touch panel 150 includes the black layer 151 (second light absorbing layer) which is formed on one face 39a side of the base material 39, the dielectric body layer 152 which is arranged on one face 39a of the base material 39 so as to cover the black layer 151, and the black layer 40 which is formed on one face 152a of the dielectric body layer 152, as shown in FIG. 15(A). That is, the light diffusing touch panel 150 is schematically configured of the base material 39, the plurality of black layers 151 (light absorbing layers) that are formed on one face 39a of the base material 39, the dielectric body layer 152 that is arranged on one face 39a of the base material 39 so as to cover the black layer 151, the black layer 40 that is formed on one face 152a of the dielectric body layer 152, and the light diffusing portion 41 that is formed on one face 152a of the dielectric body layer 152 in the same manner as the black layer 40.

In the case of manufacturing the light diffusing touch panel 150, first, the black layer 151 is formed on one face 39a of the base material 39. Next, on one face 39a side of the base material 39, the dielectric body layer 152 is formed on the black layer 151.

Subsequently, the black layer 40 is formed on one face 152a of the dielectric body layer 152 of one face 39a of the base material 39.

Next, the light diffusing portion 41 is formed.

As shown in FIG. 15(B), the black layers 40 are formed on one face 152a of the dielectric body layer 152 which is formed on one face 39a side of the base material 39. The black layers 40 form the line shape (belt shape) in the y direction which seen from the viewing side, and are connected to each other by the conductive portions 40A which are made up of the same material as the black layer 40. Hereby, the black layer 40 has the conductivity along the y axis direction on one face 152a of the dielectric body layer 152.

On the other hand, as shown in FIG. 15(C), the black layers 151 are formed on one face 39a side of the base material 39. The black layers 151 form the line shape (belt shape) in the x direction which seen from the viewing side, and are connected to each other by conductive portions 151A which are made up of the same material as the black layer 151. Hereby, the black layer 151 has the conductivity in the x direction on the other face 152b of the dielectric body layer 152.

In the light diffusing touch panel 150 of the sixth embodiment, the dielectric body layer 152 forms the dielectric layer, the black layer 40 which is formed on one face 152a of the dielectric body layer 152 forms the first conductive film, and the black layer 151 which is formed on the other face 152b of the dielectric body layer 152 forms the second conductive film. That is, in the light diffusing touch panel 150, the stacked body that is made up of the black layer 40, the dielectric body layer 152 and the black layer 151, functions as a touch panel. The first conductive film (black layer 40) and the second conductive film (black layer 151) are arranged so as to form the simple matrix structure. Therefore, if the finger touches the black layer 151, in the vicinity thereof, the capacitance of the black layer 151 is changed, and it is possible to detect the position at multipoint. Furthermore, here, as a touch panel system, the capacitance system is exemplified, but the sixth embodiment is not limited thereto.

In this manner, since the black layer 40 serves as a light absorbing layer and a first conductive film of the touch panel, and the black layer 151 serves as a light absorbing layer and a second conductive film of the touch panel, it is possible to make the light diffusing touch panel 150 be a thin type, and it is possible to manufacture the light diffusing touch panel 150 at a low cost.

### INDUSTRIAL APPLICABILITY

The present invention can be used in various types of display devices such as a liquid crystal display device, an organic electroluminescence display device, and a plasma display.

### REFERENCE SIGNS LIST

1 LIQUID CRYSTAL DISPLAY DEVICE (DISPLAY DEVICE)
2 BACKLIGHT (LIGHT SOURCE)
3 FIRST POLARIZING PLATE
4 LIQUID CRYSTAL PANEL
5 SECOND POLARIZING PLATE
6 LIQUID CRYSTAL DISPLAY BODY (DISPLAY BODY)
7 LIGHT DIFFUSING TOUCH PANEL (VIEWING ANGLE WIDENING MEMBER, LIGHT DIFFUSING MEMBER)
9 TFT SUBSTRATE
10 COLOR FILTER SUBSTRATE
11 LIQUID CRYSTAL LAYER
12 SPACER
14 TRANSPARENT SUBSTRATE
15 SEMICONDUCTOR LAYER
16 GATE ELECTRODE
17 SOURCE ELECTRODE
18 DRAIN ELECTRODE
19 TFT
20 GATE INSULATING FILM
21 FIRST INSULATING INTERLAYER
22, 23, 26 CONTACT HOLE
24 SECOND INSULATING INTERLAYER
25 PIXEL ELECTRODE
27 ALIGNMENT FILM
29 TRANSPARENT SUBSTRATE
30 BLACK MATRIX
31 COLOR FILTER
32 PLANARIZING LAYER
33 COUNTER ELECTRODE
34 ALIGNMENT FILM
36 LIGHT SOURCE
37 LIGHT GUIDE
39 BASE MATERIAL
40 BLACK LAYER (LIGHT ABSORBING LAYER)
41 LIGHT DIFFUSING PORTION
42 CONDUCTIVE FILM
44 COATING FILM
45 PHOTOMASK
47 OPENING PORTION
48 COATING FILM

1. A light diffusing touch panel comprising:
a base material having light-transmitting properties;
a light absorbing layer that is formed on one face side of the base material; and
a light diffusing portion that is formed on the one face side of the base material in the same manner as the light absorbing layer,
wherein the light diffusing portion has a light emission end face on the base material side and has a light incidence end face of which an area is greater than the area of the light emission end face on an opposite side to the base material side,
a height to the light emission end face from the light incidence end face of the light diffusing portion is greater than a layer thickness of the light absorbing layer, and
the base material or the light absorbing layer forms any one of a dielectric layer and a pair of conductive films which are arranged so as to overlap the dielectric layer.

2. The light diffusing touch panel according to claim 1,
wherein the base material forms the dielectric layer.

3. The light diffusing touch panel according to claim 1,
wherein the light absorbing layer forms one of the pair of conductive films, and
the other of the pair of conductive films is arranged on the other face side of the base material.

4. The light diffusing touch panel according to claim 1,
wherein one of the pair of conductive films is arranged between the base material and the light absorbing layer, and
the other of the pair of conductive films is arranged on the other face side of the base material.

5. The light diffusing touch panel according to claim 1,
wherein the light absorbing layer forms one of the pair of conductive films, and
the other of the pair of conductive films is arranged on the other face side of the base material through an adhesive.

6. The light diffusing touch panel according to claim 1, further comprising:
a second light absorbing layer on the other face of the base material,
wherein the light absorbing layer forms one of the pair of conductive films,
the second light absorbing layer forms the other of the pair of conductive films, and
a conductive direction of one of the pair of conductive films is orthogonal to the conductive direction of the other of the pair of conductive films.

7. The light diffusing touch panel according to claim 1,
wherein air is present in a space between the plurality of light diffusing portions.

8. The light diffusing touch panel according to claim 1,
wherein air is present in a space between the plurality of light diffusing portions,
the air forms the dielectric layer,
the light absorbing layer forms one of the pair of conductive films, and
the other of the pair of conductive films is arranged on the light incidence end face side of the light diffusing portion.

9. The light diffusing touch panel according to claim 1,
wherein among the plurality of light diffusing portions, a dimension of the light emission end face of at least one light diffusing portion is different from the dimensions of the light emission end faces of other light diffusing portions.

10. The light diffusing touch panel according to claim 1,
wherein among the plurality of light diffusing portions, an inclination angle of a side face of at least one light diffusing portion is different from the inclination angles of the side faces of other light diffusing portions.

11. The light diffusing touch panel according to claim 1,
wherein among the plurality of light diffusing portions, an inclination angle of a side face of at least one light diffusing portion varies depending on a place.

12. The light diffusing touch panel according to claim 1,
wherein a planar shape of the light diffusing portion which is seen from a normal direction of one face of the base material, is a round shape or a polygonal shape.

13. A manufacturing method for a light diffusing touch panel, comprising:
a step of forming a light absorbing layer that forms one of a pair of conductive films on one face of a base material having light-transmitting properties;
a step of forming, on the one face of the base material, a negative type photosensitive resin layer having light-transmitting properties so as to cover the light absorbing layer;
a step of irradiating the negative type photosensitive resin layer with diffused light through an opening portion of the light absorbing layer from an opposite face to the one face of the base material where the light absorbing layer and the negative type photosensitive resin layer are formed;
a step of developing the negative type photosensitive resin layer where the irradiation of the diffused light is finished, and forming, on the one face of the base material, a light diffusing portion that has a light emission end face on the base material side and has a light incidence end face of which an area is greater than the area of the light emission end face on an opposite side to the base material side; and
a step of forming the other of the pair of conductive films on the other face side of the base material.

14. A display device comprising:
a display body; and
a viewing angle widening member that is arranged on a viewing side of the display body and emits light in a state of having angle distribution of the light which is incident from the display body wider than that before the incidence,
wherein the viewing angle widening member is configured of the light diffusing touch panel according to claim 1.

15. The display device according to claim 14,
wherein the display body has a plurality of pixels which form a display image, and
among the plurality of light diffusing portions of the light diffusing touch panel, an average gap between adjacent light diffusing portions is smaller than a gap between the pixels of the display body.

16. The display device according to claim 14,
wherein the display body has a light source and a light modulation element that modulates light from the light source, and
the light source emits the light having directivity.

17. The display device according to claim 14,
wherein the display body is a liquid crystal display element.
